(19) United States
(12) Patent Application Publication
(10) Pub. No.: US 2014/0357016 A1
(43) Pub. Date: Dec. 4, 2014

(54) ORGANIC MOLECULAR FILM FORMING APPARATUS AND ORGANIC MOLECULAR FILM FORMING METHOD

(71) Applicant: Tokyo Electron Limited, Tokyo (JP)

(72) Inventors: Takashi Fuse, Nirasaki City (JP); Setsuko Shibuya, Nirasaki City (JP)

(73) Assignee: Tokyo Electron Limited, Tokyo (JP)

(21) Appl. No.: 14/291,164

(22) Filed: May 30, 2014

(30) Foreign Application Priority Data
Jun. 4, 2013 (JP) 2013-117833

(51) Int. Cl. H01L 51/00; B05C 9/12

(52) U.S. Cl. CPC H01L 51/0012; B05C 9/12
USPC 438/99; 118/723 R

(57) ABSTRACT

An organic molecular film forming apparatus 100 of forming an organic molecular film on a processing target object includes a processing chamber 11 that accommodates therein the processing target object; an organic material gas supplying unit 2 that supplies an organic material gas into the processing chamber 11; and an ultraviolet ray irradiating unit 13 that irradiates ultraviolet ray to at least one of the processing target object, the organic material gas supplied to the processing target object, and a film formed on a surface of the processing target object. At least one of the surface of the processing target object and the organic molecular film formed thereon is activated by irradiating the ultraviolet ray from the ultraviolet ray irradiating unit 13 to at least one of the processing target object, the organic material gas supplied to the processing target object, and the film formed on the processing target object.

### CROSS-REFERENCE TO RELATED APPLICATION

This application claims the benefit of Japanese Patent Application No. 2013-117833 filed on Jun. 4, 2013, the entire disclosures of which are incorporated herein by reference.

### TECHNICAL FIELD

The embodiments described herein pertain generally to an organic molecular film forming apparatus and an organic molecular film forming method for forming an organic molecular film, which is represented by a self-assembled monolayer (SAM).

### BACKGROUND

Recently, organic thin films made of organic compounds are used in various fields. An organic semiconductor film for use in an organic semiconductor device such as an organic transistor is an example of such an organic thin film.

As an organic thin film made of an organic compound, there is known a monolayer, so-called self-assembled monolayer (SAM). The self-assembled monolayer is composed of organic molecules that are self-organized in the higher order by an interaction between molecules of the organic compound and a surface of a substrate on which a thin film is formed.

A self-assembled monolayer is a monolayer in which organic molecules having, as an end group, a functional group which forms a certain chemical bond to a preset substrate are chemically bonded to a surface of the substrate and the anchored organic molecules are arranged in the ordered manner by the bonds to the surface of the substrate and by the interaction between the organic molecules. Since this self-assembled monolayer can be prepared by a very simple method, this self-assembled monolayer can be easily formed on the substrate.

Meanwhile, when forming an organic semiconductor film, electrical characteristics of an organic transistor to be manufactured may be improved by controlling wetting property and the lipophilicity of a substrate. To this end, it may be considered to use an organic thin film such as a self-assembled monolayer for the modification of the substrate. Patent Document 1 describes a modification of a surface of a substrate by forming a self-assembled monolayer using a silane coupling agent on the surface of the substrate and then forming a metal film on the self-assembled monolayer in a highly adhesive manner.

As stated above, the organic thin film such as the self-assembled monolayer is employed in modifying a surface of a substance. The self-assembled monolayer using the silane coupling agent described in Patent Document 1 has an alkyl group or a fluoroalkyl group as an organic functional group and may be used to modify a substrate surface such that the substrate surface has water-repellency.

Patent Document 1: Japanese Patent Laid-open Publication No. 2005-086147

Since, however, the self-assembled monolayer using the silane coupling agent causes a silane coupling reaction, the substrate is limited to have an O group or an OH group in a surface thereof, e.g., a SiO₂ surface. Further, an end group of the surface of the self-assembled monolayer is also limited to have a Si—(OR)₃ group or a Si—Cl₃ group. For this reason, it is difficult to apply the self-assembled monolayer to a resin substrate or the like. Thus, there is a limit in the kinds of the substrate on which the self-assembled monolayer can be formed, and a surface state of the self-assembled monolayer is also limited.

### SUMMARY

In view of the foregoing problems, example embodiments provide an organic molecular film forming apparatus and an organic molecular film forming method in which the kind of the processing target object can variously selected and the shape of the film surface can be variously formed.

In one example embodiment, an organic molecular film forming apparatus that forms an organic molecular film on a processing target object includes a processing chamber configured to accommodate therein the processing target object; an organic material gas supplying unit configured to supply an organic material gas, which contains an organic material, into the processing chamber; and an ultraviolet ray irradiating unit configured to irradiate an ultraviolet ray to at least one of the processing target object, the organic material gas supplied to the processing target object, and a film formed on a surface of the processing target object. Further, at least one of the surface of the processing target object and the organic molecular film formed thereon is activated by irradiating the ultraviolet ray from the ultraviolet ray irradiating unit to at least one of the processing target object, the organic material gas supplied to the processing target object, and the film formed on the surface of the processing target object.

In one example, the surface of the processing target object may be activated by irradiating the ultraviolet ray from the ultraviolet ray irradiating unit to the processing target object such that the surface of the processing target object is reacted with the organic material, and, at the same time, the organic molecular film formed on the processing target object may be activated by irradiating the ultraviolet ray thereto. In this case, the processing target object may be made of resin. Further, O or OH may be formed on the surface of the processing target object by irradiating the ultraviolet ray to the processing target object from the ultraviolet ray irradiating unit under an O₂ gas atmosphere or a H₂O gas atmosphere, and the O or the OH may be reacted with an end group of the organic material.

A surface of an organic monomolecular film formed on the processing target object may be activated by irradiating the ultraviolet ray to the organic monomolecular film from the ultraviolet ray irradiating unit, and an additional organic monomolecular film may further be formed on the organic monomolecular film by continuously irradiating the ultraviolet ray and supplying the organic material gas. In such a case, O or OH may be formed on the surface of the organic monomolecular film by irradiating the ultraviolet ray to the organic monomolecular film, and the additional organic monomolecular film may be further formed on the organic monomolecular film by a reaction between the O or the OH and an end group of the organic material.

An end group of the organic material gas having a binding energy lower than that of organic molecules corresponding to a main chain of the organic material may be formed by irradiating the ultraviolet ray to the organic material gas from the ultraviolet ray irradiating unit, and a chemical reaction between the end group of the organic material gas and the surface of the processing target object may be generated. In this case, a double bond of carbons in the organic material may be cleaved by irradiating the ultraviolet ray to the organic material gas, and a chemical reaction between the cleaved double bond and the surface of the processing target object may be generated

In another example embodiment, an organic molecular film forming method of forming an organic molecular film by supplying an organic material gas, which contains an organic material, onto a processing target object includes irradiating an ultraviolet ray to at least one of the processing target object, the organic material gas supplied to the processing target object, and a film formed on a surface of the processing target object such that at least one of the surface of the processing target object and the organic molecular film formed thereon is activated.

In accordance with the example embodiments, since the ultraviolet ray is irradiated to at least one of the processing target object, the organic material gas supplied to the processing target object, and the film formed on the processing target object, it may be possible to form an organic molecular film on the processing target object regardless of the kinds of the processing target object, even on a processing target object made of resin, for example. Further, by irradiating the ultraviolet rays, it is possible to form various surface states by modifying end groups of the organic material.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a cross sectional view illustrating an organic molecular film forming apparatus in accordance with a first example embodiment;

FIG. 2 provides a graph showing a relationship between an Ar gas flow rate and an organic material deposition rate when supplying a preset amount of organic material gas into a processing chamber and varying the flow rate of the Ar gas introduced into the processing chamber;

FIG. 3 is a cross sectional view illustrating a processing unit of an organic molecular film forming apparatus in accordance with a second example embodiment;

FIG. 4 is a cross sectional view illustrating a modification example of the organic molecular film forming apparatus in accordance with the second example embodiment;

FIG. 5 is a cross sectional view illustrating a processing unit of an organic molecular film forming apparatus in accordance with a third example embodiment; and

FIG. 6 is a cross sectional view illustrating a processing unit of an organic molecular film forming apparatus in accordance with a fourth example embodiment.

### DETAILED DESCRIPTION

Hereinafter, example embodiments will be described with reference to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

### First Example Embodiment

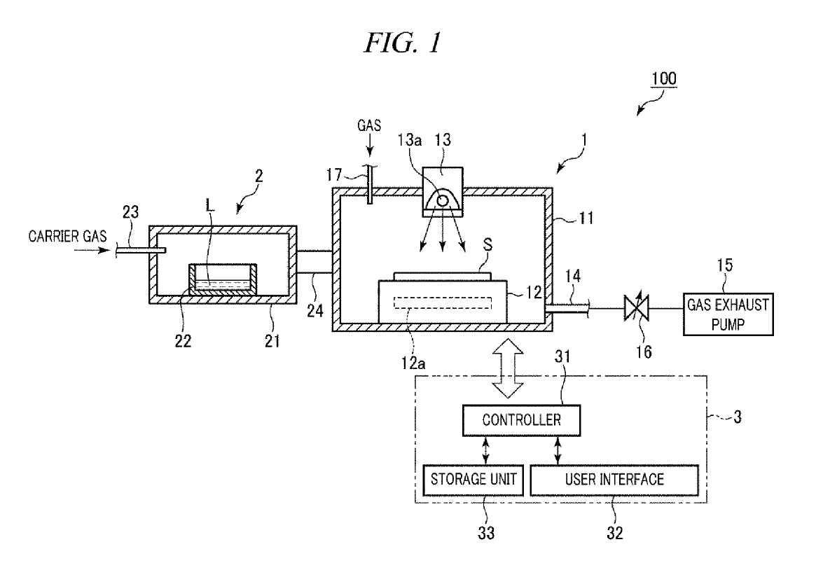

FIG. 1 is a cross sectional view illustrating an organic molecular film forming apparatus in accordance with a first example embodiment.

In the present example embodiment, the organic molecular film forming apparatus 100 includes a processing unit 1 configured to form an organic molecular film on a substrate S therein; an organic material gas generating unit (organic material gas supplying unit) 2 configured to generate a gas containing an organic material for forming an organic molecular film and supply the generated gas into the processing unit 1; and a control unit 3.

The processing unit 1 includes a processing chamber 11 configured to perform a process therein; a substrate mounting table 12 configured to hold thereon the substrate S within the processing chamber 11; an ultraviolet ray (UV) irradiating unit 13 configured to irradiate an ultraviolet ray toward the substrate 5; a gas exhaust line 14 configured to evacuate the inside of the processing chamber 11; a gas exhaust pump 15 connected to the gas exhaust line 14; a pressure control valve 16 provided at the gas exhaust line 14; and a gas inlet line 17 configured to introduce a preset gas into the processing chamber 11 when necessary. Further, a loading/unloading opening (not shown) through which the substrate S is loaded and unloaded is formed at a sidewall of the processing chamber 11. The loading/unloading opening is opened and closed by a gate valve.

A temperature control device 12a configured to control a temperature of the substrate S is provided in the substrate mounting table 12. The temperature control device 12a may include either a heater configured to heat the substrate S or a temperature control medium flow path configured to allow a temperature control medium adjusted to have a certain temperature to flow therethrough, or both of the heater and the temperature control medium flow path. Besides a substrate having a SiO₂ surface, a substrate having a surface made of a resin or others may also be used as the substrate S.

The ultraviolet ray irradiating unit 13 includes a UV lamp 13a configured to irradiate UV light. The ultraviolet ray irradiating unit 13 is configured to irradiate UV light to at least one of a surface of the substrate S, an organic material gas supplied onto the substrate S, and an organic material deposited on the surface of the substrate S, so that the substrate S or an organic molecular film (typically, a SAM film) formed thereon can be modified.

By way of non-limiting example, an O₂ gas or an H₂O gas may be introduced from the gas inlet line 17, so that the inside of the processing chamber 11 can be set to be in the O₂ gas atmosphere or the H₂O gas atmosphere.

The inside of the processing chamber 11 may be evacuated by the gas exhaust pump 15 through the gas exhaust line 14, so that the inside of the processing chamber 11 can be set to be in a desired depressurized atmosphere. Here, it is possible to set the inside of the processing chamber 11 to be in an atmospheric pressure. Since, however, the UV light irradiation range increases and impurities decreases as the pressure within the processing chamber 11 decreases, it may be desirable to set the inside of the processing chamber 11 to be in a depressurized (vacuum) atmosphere.

The organic material gas generating unit 2 includes a gas generating vessel 21; an organic material receptacle 22 provided within the gas generating vessel 21; a carrier gas inlet line 23 configured to introduce a carrier gas into the gas generating vessel 21; and an organic material gas supply line 24 configured to supply the organic material gas generated in the gas generating vessel 21 into the processing chamber 11. The organic material gas vaporized from an organic material L of a liquid phase in the organic material receptacle 22 is carried by the carrier gas and supplied into the processing chamber 11 via the organic material gas supply line 24. If the vaporization is not sufficient or the organic material is in a solid phase at a room temperature, a heater may be provided at the organic material receptacle 22.

The control unit 3 includes a controller 31 having a microprocessor (computer) for controlling respective components of the organic molecular film forming apparatus 100. The controller 31 is configured to control, for example, a flow rate of the carrier gas from the carrier gas inlet line 23, an output of the UV lamp 13a of the ultraviolet ray irradiating unit 13, an openness degree of the pressure control valve 16, an output of the temperature control device 12a, and so forth. The controller 31 is connected to a user interface 32 including a keyboard through which an operator inputs commands to manage the organic molecular film forming apparatus 100; a display that visually displays an operational status of the organic molecular film forming apparatus 100; and so forth. The controller 31 is also connected to a storage unit 33 that stores therein processing recipes as control programs for implementing various operations in a film forming process performed in the organic molecular film forming apparatus 100 under the control of the controller 31 or control programs for implementing a certain process in each component of the organic molecular film forming apparatus 100 based on processing conditions; various databases; and so forth. The processing recipes are stored on an appropriate storage medium within the storage unit 33. A necessary recipe is retrieved from the storage unit 33 and executed by the controller 31, so that a desired process is performed in the organic molecular film forming apparatus 100 under the control of the controller 31.

Now, an operation of the organic molecular film forming apparatus 100 having the above-described configuration will be discussed.

In the present example embodiment, a SAM film is formed on a substrate S as an organic molecular film.

Generally, in forming the SAM film, a material represented by a general formula of R″—Si(OR)₃ is used as a typical organic material, and a substrate having a SiO₂ surface is used. A reaction as follows, called silane coupling, is generated on the surface of the substrate.

R′—Si(OR)₃+H₂O→R′—Si(OH)₃+ROH

R′—Si(OH)₃+SiO (surface)→R′—SiO+Si (surface)+H₂O

Here, R′ denotes an alkyl group, and OR denotes a group that can be hydrolyzed such as a methoxy group or an ethoxy group. An example of such an organic material may be, but not limited to, hexamethyldisilazane (HMDS).

Through this reaction, a monomolecular alkyl group (R′) adheres to the SiO₂ surface, and a surface property thereof is changed.

In this reaction, an end group of the SAM on a front surface side thereof (opposite to the substrate) needs to be Si—(OR)₃ (methoxy or ethoxy group) or Si—Cl₃ (halogen), and a surface of the substrate also needs to be a silicon oxide film.

In order to change surface functionality, the SAM needs to have various end groups including the alkyl group (e.g., CH₃) on the front surface side thereof. Conventionally, it has been difficult to design molecules such that end groups on both sides of the SAM are controlled as desired. Further, since the silane coupling reaction is a dehydration/hydration reaction, it is essentially required that O or OH exists on the surface of the substrate. Conventionally, however, O or OH is difficult to exist on a resin surface or the like. Thus, it has been difficult to use a resin substrate or the like in the silane coupling reaction.

Further, in an organic material having an alkyl group as an end group, a film forming process is performed by the dehydration reaction between O or OH on the surface of the substrate and Si(OR)₃ of the organic material. Accordingly, it has been difficult to form a film having a sufficient thickness more than a monolayer.

To solve the problems, in the present example embodiment, at least one of the surface of the substrate S and the surface of the organic molecular film are modified by irradiating UV light from the UV lamp of the ultraviolet ray irradiating unit 13.

Below, specific processes will be explained

In a first process, (1) the inside of the processing chamber 11 is set to be in the O₂ gas atmosphere or the H₂O gas atmosphere by introducing an O₂ gas or an H₂O gas into the processing chamber 11; and O or OH is formed on a surface of the substrate S where O and OH do not exist by irradiating UV light to the substrate S under this atmosphere. Further, (2) at the same time, end groups of an organic molecular film (SAM) at a front surface side thereof are also activated by irradiating the UV light thereto. Furthermore, (3) through these operations, a reaction between the organic material (SAM material) and the substrate S is accelerated, so that an organic molecular film having a desired organic end surface is formed.

The aforementioned operations (1) to (3) may be achieved by providing the ultraviolet ray irradiating unit at a position from which the UV light can be irradiated to the surface of the substrate and to a flow path through which the organic material-containing gas passes.

In a second process, (1) an organic monomolecular film having, e.g., an alkyl group as an end group is formed without irradiating the UV light. Further, (2) the irradiation of the UV light is begun after the organic molecular film is formed. At this time, O or OH is formed on the alkyl group as a result of irradiating the UV light. If the supply of the organic material is not stopped at this time, the O or OH formed on the alkyl group may react with Si—(RO)₃of the organic material. Through this process, after a monomolecular layer is formed, it is still possible to form an additional monomolecular layer thereon. Thus, it is possible to form an organic molecular film composed of stacked monomolecular layers. This process may be referred to as MLD (Molecular Layer Deposition), which is similar to ALD (Atomic Layer Deposition) in which a required film is formed by stacking a multiple number of atomic layers.

Although the above example embodiment has been described based on the silane coupling reaction, the second process may not be limited thereto. Further, in the second process, if the substrate S is a resin substrate or the like, by irradiating UV light under the O₂ gas atmosphere or the H₂O gas atmosphere prior to performing the operation (1), O or OH can be formed on the surface of the substrate S.

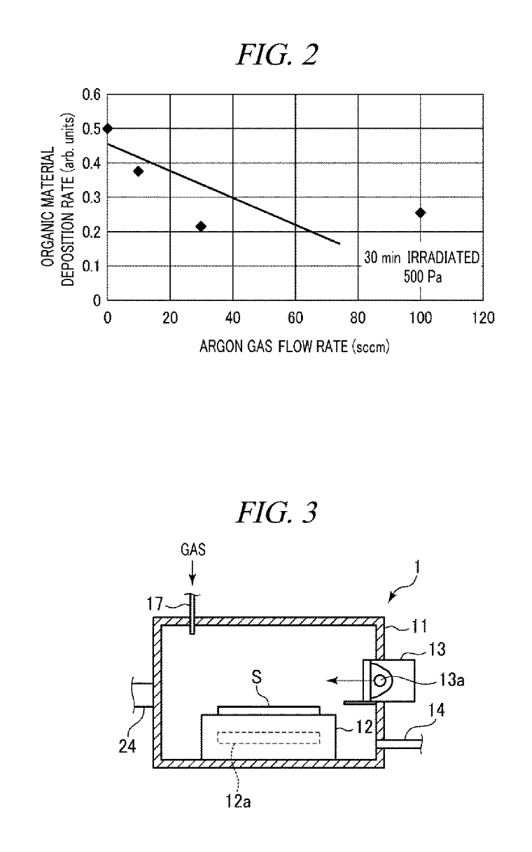

When performing the second process, as the intensity of the UV light irradiated to the film increases, the effect of activating the organic material is improved, so that a deposition rate of the organic material can be increased. This relationship is shown in FIG. 2. FIG. 2 depicts a graph showing a relationship between an Ar gas flow rate and an organic material deposition rate when supplying a preset amount of organic material gas into the processing chamber and varying the flow rate of the Ar gas introduced into the processing chamber. When the UV light of a preset intensity is radiated from the UV lamp, as the Ar gas flow rate increases, the UV light irradiation range may be shortened and the intensity of the UV light irradiated to the organic molecular film may be decreased. As can be seen from FIG. 2, as the Ar gas flow rate decreases and the irradiation intensity of the UV light increases, the organic material deposition rate, i.e., a thickness of the organic molecular film increases.

### Second Example Embodiment

Now, a second example embodiment will be discussed.

FIG. 3 is a cross sectional view illustrating a processing unit of an organic molecular film forming apparatus in accordance with a second example embodiment. As shown in FIG. 3, in the second example embodiment, an ultraviolet ray irradiating unit 13 is provided at the sidewall of the processing chamber 11. In this configuration, the UV light is not irradiated to the surface of the substrate S, and the UV light from the UV lamp 13a is irradiated only to the organic material-containing gas supplied to above the substrate S.

This configuration is suitable for performing the second process. That is, in the second process, it is required that the UV light is irradiated only to an organic material gas or an organic molecular film without being irradiated to the substrate S. By irradiating the UV light from the sidewall in this way, such a requirement can be satisfied.

Further, the configuration as depicted in FIG. 3 is also suitable for a third process to be described below. In the third process, there is formed an end group having a binding energy lower than that of organic molecules corresponding to a main chain by irradiating the UV light to the organic material gas, and a chemical reaction between the end group and a substrate surface is generated. By way of example, by irradiating the UV light to molecules having double bond of carbon (C═C), the double bond may be cleaved, and it is possible to form an organic molecular film by a chemical reaction between the cleaved double bond and the substrate surface.

Such a third process may not be limited to the silane coupling reaction but may also be applied to other reactions. Consequently, it is possible to select various organic materials. Moreover, if a surface of an organic monomolecular film formed through the third process could be activated by UV light, it may be possible to form an organic monomolecular film on the previously formed organic monomolecular film as in the second process. Thus, an organic molecular film composed of stacked monomolecular films can be formed.

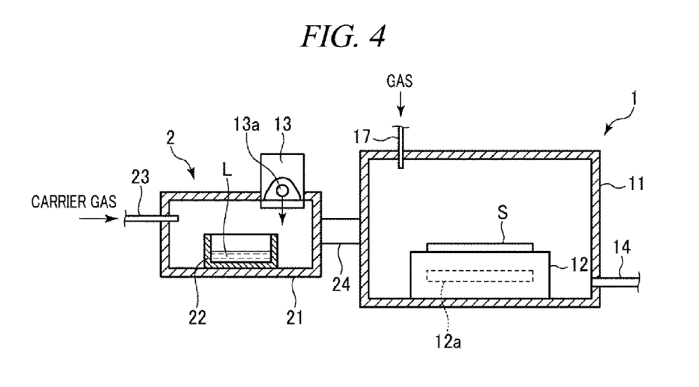

In the aspect of irradiating the UV light only to the organic material gas without irradiating the UV light to the substrate S, the ultraviolet ray irradiating unit 13 may be provided at the gas generating vessel 21 of the organic material gas generating unit 2, as illustrated in FIG. 4. At a position where the ultraviolet ray irradiating unit 13 is provided in FIG. 4, it is still possible to irradiate the UV light only to the organic material gas without irradiating the UV light to the substrate S.

### Third Example Embodiment

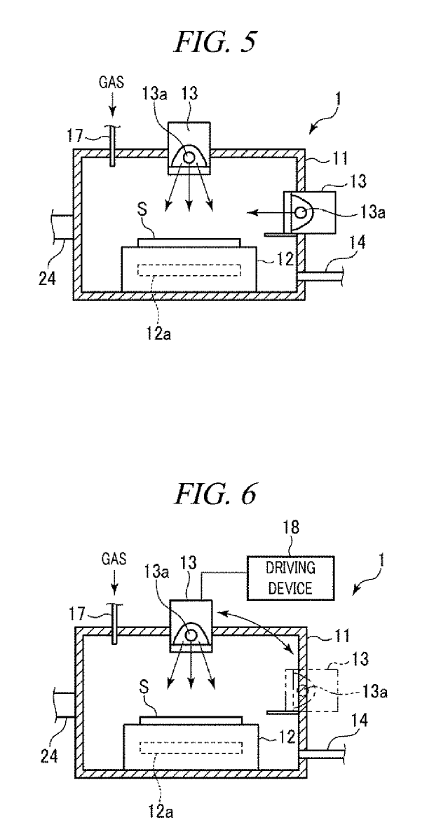

In a third example embodiment, as depicted in FIG. 5, the ultraviolet ray irradiating units 13 are respectively provided at a position directly above the substrate S, where the UV light is irradiated to the substrate S, within the processing chamber 11 and at a sidewall position of the processing chamber 11, where the UV light is not irradiated to the substrate S.

With this configuration, it is possible to perform a process without irradiating the UV light to the substrate S and a process of irradiating the UV light to the substrate S.

The ultraviolet ray irradiating unit 13, which do not irradiate the UV light to the substrate S, may be provided within the gas generating vessel 21 of the organic material gas generating unit 2, as depicted in FIG. 4.

### Fourth Example Embodiment

In a fourth example embodiment, as shown in FIG. 6, the ultraviolet ray irradiating unit 13 is configured to be moved between a position directly above the substrate S, where the UV light is irradiated to the substrate S, and the sidewall position of the processing vessel 11, where the UV light is not irradiated to the substrate S, by a driving device 18.

In this configuration, the ultraviolet ray irradiating unit 13 may be located at the sidewall position in a process where the UV light is not irradiated to the substrate S, whereas the ultraviolet ray irradiating unit 13 may be located at the position directly above the substrate S in a process where the UV light is irradiated to the substrate S. Thus, it is possible to perform a process without irradiating the UV light to the substrate S and a process of irradiating the UV light to the substrate S.

### Effects of the First to Fourth Example Embodiments

In the apparatuses according to the first to fourth example embodiments, when forming an organic molecular film, typically, a SAM film, it is possible to irradiate the UV light to at least one of the surface of the substrate S, the organic material supplied onto the substrate S and the film formed on the surface of the substrate S. Thus, regardless of the kinds of the substrate, it may be possible to form an organic molecular film on the substrate, even on a resin substrate, for example. Further, by irradiating the UV light, end groups of the organic material can be modified and various surface states can be formed. Furthermore, it may be also possible to set a thickness of the organic molecular film to a desired thickness.

To elaborate, by using the apparatuses in accordance with the first to fourth example embodiments, the above-described first to third processes can be performed, and, accordingly, the following effects can be achieved.

In the first process, by irradiating the UV light to the substrate S under the O₂ gas atmosphere or the H₂O gas atmosphere, it is possible to form O or OH on the surface of the substrate S even in case that the substrate S is a resin substrate in which neither O nor OH exists. Accordingly, a reaction between the substrate and the organic material can be generated, so that an organic molecular film can be formed. Further, by irradiating the UV light, end groups of the organic molecular film at the front surface side thereof can be activated, so that it is possible to form an organic molecular film having a desired end surface. By way of example, in the conventional silane coupling reaction, the end group is limited to a preset kind, and a surface state is also limited to water-repellency. However, by irradiating the UV light, it is possible to select the various end groups, and, thus, it is possible to obtain various surface states such as oil-repellency, hydrophilic property, and lipophilicity as well as water-repellency.

Further, in the second process, by irradiating the UV light after forming an organic monomolecular film having, e.g., an alkyl group as an end group, O or OH is formed on the alkyl group. If the organic material is continuously supplied, a reaction between the O or OH formed on the alkyl group and Si—(RO)₃ of the organic material is generated through a MLD type process. As a result, it is possible to stack a desired number of organic monomolecular films on top of each other, and possible to form an organic molecular film having a required thickness. Further, the second process may also be applied to an organic material other than one using a silane coupling reaction. Further, after activating a surface of a firstly formed organic monomolecular film by irradiating the UV light thereto, it is possible to form an organic monomolecular film of a different material on the activated surface of the previously formed organic monomolecular film. Thus, a variation of a surface state of the organic molecular film formed thereon can be increased.

Furthermore, in the third process, by irradiating the UV light to the organic material gas, there is formed an end group having a binding energy lower than that of organic molecules corresponding to the main chain, and a chemical reaction between the end group and the substrate surface is generated. Accordingly, various reactions may be generated without being limited to the silane coupling reaction. As a result, it is possible to select various organic materials, and it is also possible to variously form an organic molecular film. Further, by activating the surface of the organic monomolecular film formed through this process by the UV light, an organic molecular film composed of stacked monomolecular films having a desired thickness can be formed through the MLD type film formation, as in the second process.

(Other Applications)

Here, it would be appreciated that the example embodiments of the present disclosure have been described herein for purposes of illustration, and that various modifications may be made without departing from the scope and spirit of the present disclosure. Accordingly, the various embodiments disclosed herein are not intended to be limiting. For example, in the above-described example embodiments, an organic material gas vaporized from the organic material of the liquid phase is supplied by a carrier gas. However, the example embodiments may not be limited thereto, and the organic material gas may be supplied by bubbling or by a vaporizer or the like. Furthermore, in the above example embodiments, the organic molecular film is described to be formed on the substrate. However, a processing target object on which the organic molecular film is to be formed may not be limited to the substrate. By way of non-limiting example, by applying the example embodiments to a vessel-shaped processing target object, it is possible to form the organic molecular film on the surface of the processing target object even in case that the processing target object is made of resin or the like. Thus, a vessel having a water-repellent surface can be manufactured.

Moreover, the above example embodiments have been described for the case of forming the organic molecular film on the substrate. However, by forming the organic molecular film through the example embodiments, it is possible to form a surface having a desired function, such as a water-repellent surface or an anti-fouling surface, on any kinds of processing target object.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. An organic molecular film forming apparatus that forms an organic molecular film on a processing target object, comprising:
a processing chamber configured to accommodate therein the processing target object;
an organic material gas supplying unit configured to supply an organic material gas, which contains an organic material, into the processing chamber; and
an ultraviolet ray irradiating unit configured to irradiate an ultraviolet ray to at least one of the processing target object, the organic material gas supplied to the processing target object, and a film formed on a surface of the processing target object,
wherein at least one of the surface of the processing target object and the organic molecular film formed thereon is activated by irradiating the ultraviolet ray from the ultraviolet ray irradiating unit to at least one of the processing target object, the organic material gas supplied to the processing target object, and the film formed on the surface of the processing target object.

2. The organic molecular film forming apparatus of claim 1,
wherein the surface of the processing target object is activated by irradiating the ultraviolet ray from the ultraviolet ray irradiating unit to the processing target object such that the surface of the processing target object is reacted with the organic material, and, at the same time, the organic molecular film formed on the processing target object is activated by irradiating the ultraviolet ray thereto.

3. The substrate processing apparatus of claim 2,
wherein the processing target object is made of resin,
O or OH is formed on the surface of the processing target object by irradiating the ultraviolet ray to the processing target object from the ultraviolet ray irradiating unit under an O₂ gas atmosphere or a H₂O gas atmosphere, and the O or the OH is reacted with an end group of the organic material.

4. The organic monomolecular film forming apparatus of claim 1,
wherein a surface of an organic monomolecular film formed on the processing target object is activated by irradiating the ultraviolet ray to the organic monomolecular film from the ultraviolet ray irradiating unit, and
an additional organic monomolecular film is further formed on the organic monomolecular film by continuously irradiating the ultraviolet ray and supplying the organic material gas.

5. The organic monomolecular film forming apparatus of claim 4,
wherein O or OH is formed on the surface of the organic monomolecular film by irradiating the ultraviolet ray to the organic monomolecular film, and
the additional organic monomolecular film is further formed on the organic monomolecular film by a reaction between the O or the OH and an end group of the organic material.

6. The organic monomolecular film forming apparatus of claim 1,
wherein an end group of the organic material gas having a binding energy lower than that of organic molecules corresponding to a main chain of the organic material is formed by irradiating the ultraviolet ray to the organic material gas from the ultraviolet ray irradiating unit, and a chemical reaction between the end group of the organic material gas and the surface of the processing target object is generated.

7. The organic monomolecular film forming apparatus of claim 6,
wherein a double bond of carbons in the organic material is cleaved by irradiating the ultraviolet ray to the organic material gas, and a chemical reaction between the cleaved double bond and the surface of the processing target object is generated.

8. An organic molecular film forming method of forming an organic molecular film by supplying an organic material gas, which contains an organic material, onto a processing target object, the method comprising:
irradiating an ultraviolet ray to at least one of the processing target object, the organic material gas supplied to the processing target object, and a film formed on a surface of the processing target object such that at least one of the surface of the processing target object and the organic molecular film formed thereon is activated.

9. The organic molecular film forming method of claim 8,
wherein the surface of the processing target object is activated by irradiating the ultraviolet ray to the processing target object such that the surface of the processing target object is reacted with the organic material, and, at the same time, the organic molecular film formed on the processing target object is activated by irradiating the ultraviolet ray thereto to have a preset surface state.

10. The organic molecular film forming method of claim 9,
wherein the processing target object is made of resin,
O or OH is formed on the surface of the processing target object by irradiating the ultraviolet ray to the processing target object under an O₂ gas atmosphere or a H₂O gas atmosphere, and the O or the OH is reacted with an end group of the organic material.

11. The organic molecular film forming method of claim 8,
wherein a surface of an organic monomolecular film formed on the processing target object is activated by irradiating the ultraviolet ray to the organic monomolecular film, and
an additional organic monomolecular film is further formed on the organic monomolecular film by continuously irradiating the ultraviolet ray and supplying the organic material gas.

12. The organic molecular film forming method of claim 11,
wherein O or OH is formed on the surface of the organic monomolecular film by irradiating the ultraviolet ray to the organic monomolecular film, and
the additional organic monomolecular film is further formed on the organic monomolecular film by a reaction between the O or the OH and an end group of the organic material.

13. The organic molecular film forming method of claim 8,
wherein an end group of the organic material gas having a binding energy lower than that of organic molecules corresponding to a main chain of the organic material is formed by irradiating the ultraviolet ray to the organic material gas, and a chemical reaction between the end group of the organic material gas and the surface of the processing target object is generated.

14. The organic molecular film forming method of claim 13,
wherein a double bond of carbons in the organic material is cleaved by irradiating the ultraviolet ray to the organic material gas, and a chemical reaction between the cleaved double bond and the surface of the processing target object is generated.
